(19) United States
(12) Patent Application Publication
(10) Pub. No.: US 2025/0389027 A1
(43) Pub. Date: Dec. 25, 2025

(54) DIRECT DIFFUSION BONDING OF MATERIALS WITH SURFACE TREATMENT

(71) Applicant: Diamond Foundry Inc., South San Francisco, CA (US)

(72) Inventor: Jean-Claude Harel, San Jose, CA (US)

(73) Assignee: Diamond Foundry Inc., South San Francisco, CA (US)

(21) Appl. No.: 19/214,355

(22) Filed: May 21, 2025

Related U.S. Application Data
(60) Provisional application No. 63/662,988, filed on Jun. 21, 2024.

(51) Int. Cl. C23C 16/56; C23C 16/06

(52) U.S. Cl. CPC C23C 16/56; C23C 16/06

(57) ABSTRACT

A composition of matter includes a diamond substrate and a second substrate material. An interfacial region formed between the diamond substrate material and the second material substrate wherein the interfacial region incorporates transition metal atoms and diffusion barrier metal atoms are integrated with at least a crystal structure of the diamond substrate.

### CLAIM OF PRIORITY

This application claims the priority benefit if U.S. Provisional Patent Application No. 63/662,988 filed Jun. 21, 2024, the entire disclosures of which are incorporated herein by reference.

### FIELD OF THE DISCLOSURE

Aspects of the present disclosure relate to bonding materials, more specifically aspects of the present disclosure relate to bonding diamond substrates.

### BACKGROUND OF THE DISCLOSURE

Diamond has many positive attributes which would be useful for applications such as electronics and jewelry. Diamond is a difficult material to incorporate into devices because it is mostly unreactive and has a high surface hardness. This combination of factors made it hard to bond diamond to other materials as the carbon atoms of the diamond would not react to most solvents or adhesives. Additionally in the past it was not possible to create larger sheets of diamond. The limitation on size of the diamond meant that even if bonding were possible, it was not possible to create a diamond large enough for many purposes.

Recently, improvements in diamond substrate production by Diamond Foundry Inc. have allowed the production of larger sheets of diamond substrates. Several techniques have been developed to bond diamond to a second material. One such technique is surface activated bonding (SAB). SAB requires the use of ions to amorphized the surface of diamond creating a reactive surface and reducing lattice mismatch. This ionization step is costly and creates an activated surface that may produce unwanted interactions with the second material. For example, some oxide may be produced at the interface, which weakens the boding.

It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1A is a schematic diagram of a diamond substrate bonded to a second material substrate via direct diffusion bonding with a bonding layer, diffusion barrier, and metal adhesion layer on both substrates according to an aspect of the present disclosure.

FIG. 1B is a schematic diagram of a diamond substrate bonded to a second material substrate via direct diffusion bonding with a bonding layer, and diffusion barrier, on both substrates according to an aspect of the present disclosure.

FIG. 1C is a schematic diagram of a diamond substrate bonded to a second material substrate via direct diffusion bonding with a bonding layer on both substrates according to an aspect of the present disclosure.

FIG. 1D is a schematic diagram of a diamond substrate bonded to a second material substrate via direct diffusion bonding with a bonding layer, diffusion barrier, and adhesion layer on the diamond substrate and a nickel diffusion barrier and metal adhesion layer on the second material substrate according to an aspect of the present disclosure.

FIG. 1E is a schematic diagram of a diamond substrate bonded to a second material substrate via direct diffusion bonding with a bonding layer, diffusion barrier, and metal adhesion layer on the diamond substrate according to an aspect of the present disclosure.

FIG. 2 is a block diagram depicting a method for direct diffusion bonding with surface treatment of a diamond substrate with a second material substrate according to an aspect of the present disclosure.

FIGS. 3A-3B graphically depict polishing steps in the method for direct diffusion bonding with surface treatment of a diamond substrate with a second material substrate according to an aspect of the present disclosure.

FIG. 4A-4B graphically depict titanium bonding layer deposition steps in the method for direct diffusion bonding with surface treatment of a diamond substrate with a second material substrate according to an aspect of the present disclosure.

FIG. 5A-5B graphically depict nickel diffusion layer deposition steps in the method for direct diffusion bonding with surface treatment of a diamond substrate with a second material substrate according to an aspect of the present disclosure.

FIG. 6A-6B graphically depict metal adhesion layer deposition steps in the method for direct diffusion bonding with surface treatment of a diamond substrate with a second material substrate according to an aspect of the present disclosure.

FIG. 7A-7B graphically depict substrate surface treatment stacks prior to a bonding step in the method for direct diffusion bonding with surface treatment of a diamond substrate with a second material substrate according to an aspect of the present disclosure.

FIG. 8 graphically depicts a bonding step in the method for direct diffusion bonding with surface treatment of a diamond substrate with a second material substrate according to an aspect of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed invention.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present disclosure can be positioned in a number of different orientations, the directional terminology is used for purposes of illustration and is in no way limiting. It is to be understood that other embodiments may be utilized, and structural or logical changes may be made without departing from the scope of the present invention. The following detailed description, therefore, is not to be taken in a limiting sense, and the scope of the present invention is defined by the appended claims.

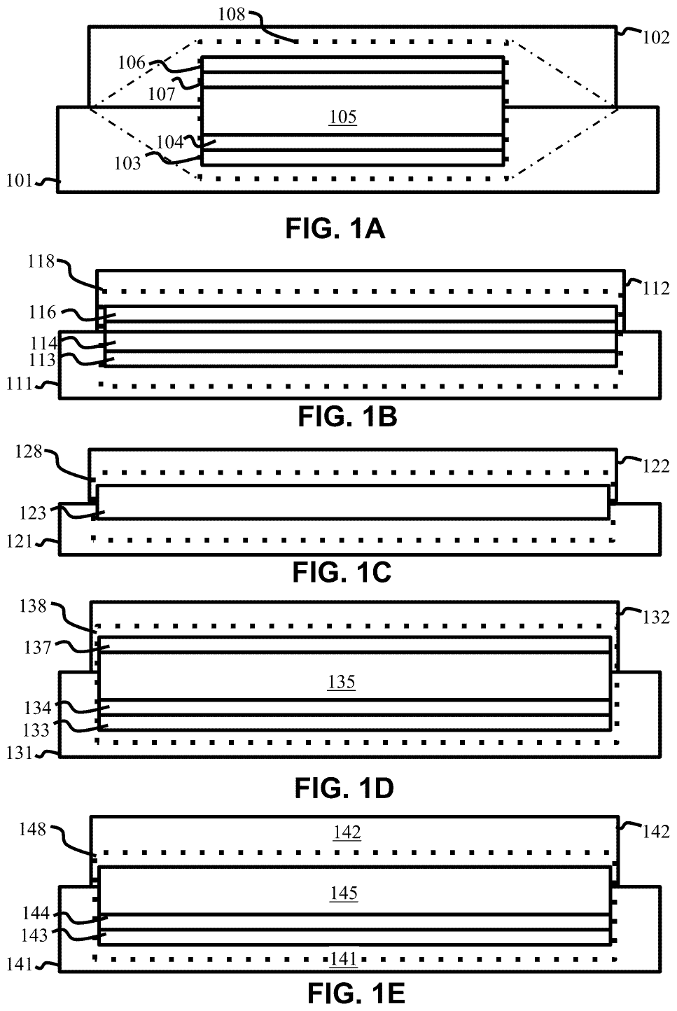

FIG. 1A is a side view diagram of a diamond substrate bonded to a second material substrate via direct diffusion bonding with a titanium bonding layer, nickel diffusion barrier, and metal adhesion layer on both substrates according to an aspect of the present disclosure. As shown a composition of matter may be created with direct diffusion bonding which tightly adheres a diamond substrate 101 to a second material substrate 102. An interfacial region 108 is integrated into the crystal lattice of the diamond substrate 101 and the second material substrate 102 after direct diffusion bonding. Thus, direct diffusion bonding causes a bond between the substrates and on an atomic level. Here, unlike previous methods such as sintering or soldering direct bonding does not create a separate adhesive layer between the two substrates and instead the interfacial region is integrated into the substrates. Details of the interfacial region 108 are shown in the expanded section indicated by the dashed lines and discussed further below.

To facilitate bonding specific materials are layered over the surfaces of at least the diamond substrate before heat and pressure are applied to bond the two substrates. These materials are incorporated into the interfacial region 108. Depending upon the type of second material substrate that is being bonded to the diamond substrate, the materials layered upon the second material substrate may differ. In the example shown in FIG. 1A the second material substrate may be a non-metal, metalloid, metal alloy, etc. such as silicon, germanium, tin, lead, aluminum, copper, high carbon steel, etc. In some implementations, the second material may be another diamond substrate. The diamond substrate may be a polycrystalline diamond substrate or more preferably a Single Crystal Diamond (SCD) substrate. The SCD substrate may be 50 micrometers to 300 micrometers in thickness and have lateral dimensions of less than or equal to 30 millimeters in length by 30 millimeters in width. As used herein, “lateral dimensions” refers to dimensions other than thickness, such as length, width or diameter”. The first layer on the diamond substrate is a bonding layer 103 which may include a layer of transition metal atoms, e.g., titanium, deposited on the surface of the diamond substrate before heat and pressure bonding. Other transition metals could be used if chemically compatible with other constituent layers of the interfacial region 108. Likewise, a bonding layer 106 of a transition metal, such as titanium, may be deposited on a surface of the second material substrate 102. The titanium atoms may act as an intermediate between the carbon atoms of the diamond and atoms of material, e.g., metal, being bonded to diamond.

A diffusion barrier layer 104 may be formed over the bonding layer 103 on the diamond substrate 101. Similarly, a diffusion barrier layer 107 may be formed over the bonding layer 106 on the surface of the second material substrate 102. The diffusion barrier layers 104, 107 maybe made from a metal such as Nickel deposited over the respective bonding layers 103, 106. The diffusion barrier layers prevent diffusion of atoms into the bonding layers 103, 106. Metals other than Nickel may be used for the diffusion barrier layer 104 if chemically compatible with the other layers in the interfacial region 108 and the intended application for the composition of matter. For example, Iron may be used in implementations where corrosion is not a concern.

The next layer in this composition of matter is an adhesion layer 105. The adhesion layer 105 may include a group 11 metal such as copper, silver, palladium, gold or an alloy thereof. Before the bonding step the adhesion layer may be deposited on both the diffusion barrier 104 over the diamond substrate 101 and the diffusion barrier 107 over the second material substrate 102.

After bonding, the bonding layer, diffusion layer and adhesion layer are integrated into an interfacial region 108 created in areas of the diamond substrate 101 and second material substrate 102. On the diamond substrate side of the interfacial region 108 atoms of the bonding layer 103 bond to the carbon atoms of the diamond substrate 101 and to atoms of the diffusion barrier and/or adhesion layer 105, integrating the atoms into lattice of the diamond. Similarly, the atoms of the bonding layer 106 bond to atoms of the bonding layer on the second material substrate and the diffusion barrier. For the second material substrate the bonding layer may likewise bond to atoms of the second material and the diffusion barrier, integrating them into the crystal lattice of the second material. The above-described composition of matter creates a solid bonded connection between the diamond substrate and the second material substrate. As shown, the bonding layers 103, 106, diffusion barrier layers 104, 107 and adhesion layer 105 have integrated with the carbon atom lattice of the diamond substrate 101 and the second material substrate 102 leaving no distinct layers of material between the two substrates.

FIG. 1B is a side view diagram of a diamond substrate bonded to a second material substrate via direct diffusion bonding with a bonding layer, diffusion barrier, on both substrates according to an aspect of the present disclosure. In this alternative implementation the adhesion layer has been omitted and the diffusion barrier layer 114 on both diamond substrate 111 and the second material substrate 112 are bonded together in the interfacial region 118. The bonding layer 113 bonds the nickel atoms to the carbon atoms of the diamond substrate 111 and the bonding layer 116 bonds the atoms second material substrate to the diffusion barrier layer 114. Such implementations may be used where the diffusion barrier material can also act as the adhesion layer.

FIG. 1C is a cutaway side view diagram of a diamond substrate bonded to a second material substrate via direct diffusion bonding with a bonding layer on both substrates according to an aspect of the present disclosure. In this alternative implementation the adhesion layer and diffusion layer have been omitted. Here, the bonding layer 123 bonds the diamond substrate 121 to the second material substrate 122 in the interfacial region 128. Such a configuration might be used, e.g., where the second material substrate 122 is copper or another metal of group 11.

FIG. 1D is a schematic diagram of a diamond substrate bonded to a second material substrate via direct diffusion bonding with a bonding layer, diffusion barrier, and adhesion layer on the diamond substrate and a diffusion barrier and adhesion layer on the second material substrate according to an aspect of the present disclosure. In this implementation, the second material substrate is compatible with bonding to the diffusion barrier layer and/or adhesion layer without the use of an intermediate bonding layer. Here, the interfacial region 138 includes a bonding layer 133 formed on a first material substrate 131. A first diffusion barrier layer 134 is bonded to the bonding layer and the diffusion barrier layer 134 is bonded to an adhesion layer 135, which is also bonded to a second barrier layer 137. The second barrier layer 137 is formed on the second material substrate 132.

FIG. 1E is a schematic diagram of a composition of matter having a diamond substrate 141 bonded to a second material substrate 142 via direct diffusion bonding with a bonding layer 143, diffusion barrier 144, and adhesion layer 145 on the diamond substrate according to an aspect of the present disclosure. In this implementation the second material substrate 142 is the same material or material compatible with bonding to the adhesion layer 145. Thus, the diffusion barrier layer and bonding layer have been omitted. Here, the interfacial region 148 includes a bonding layer 143 bonded to diffusion barrier layer 144 and the diffusion barrier layer 144 is bound to the adhesion layer 145 which is also bound to the second material substrate 142. Such an implementation may be useful, e.g., when bonding a second material substrate 142 made of copper, silver, gold, or palladium to the diamond substrate 141.

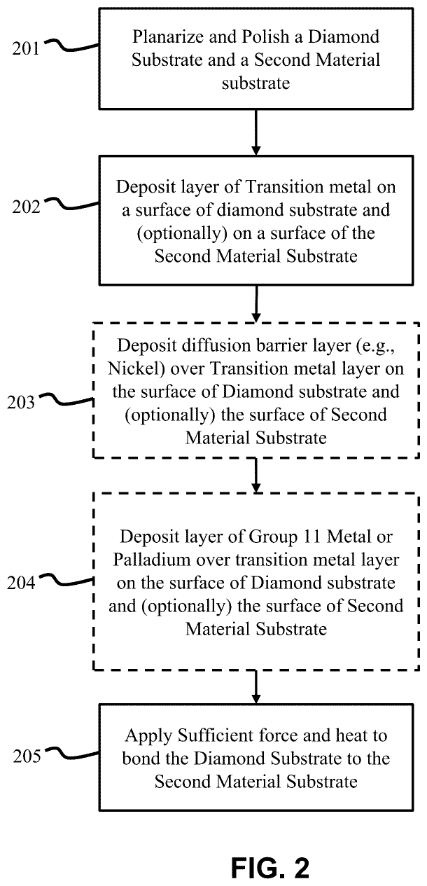

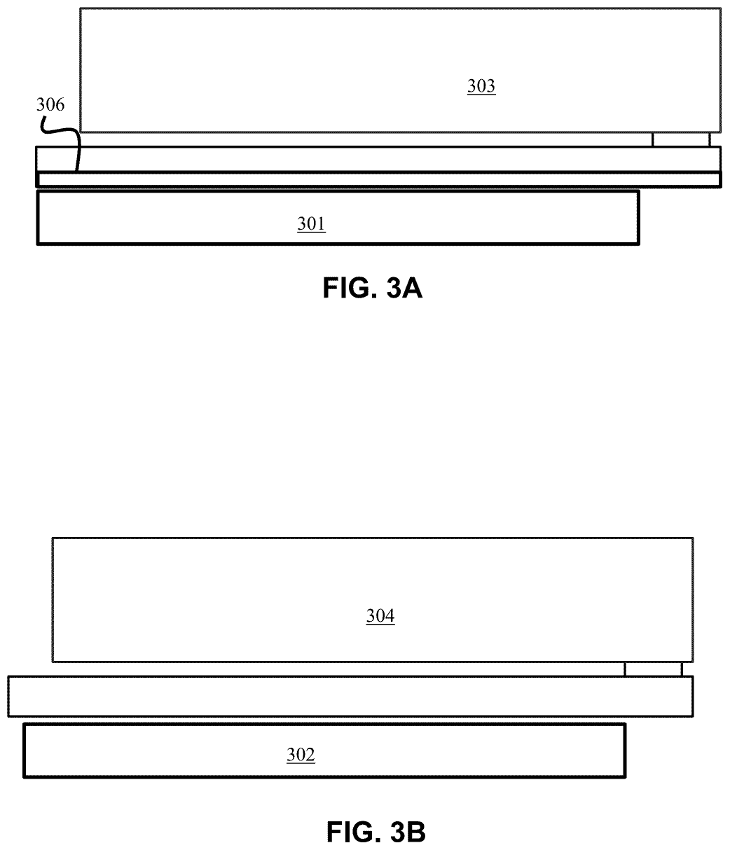

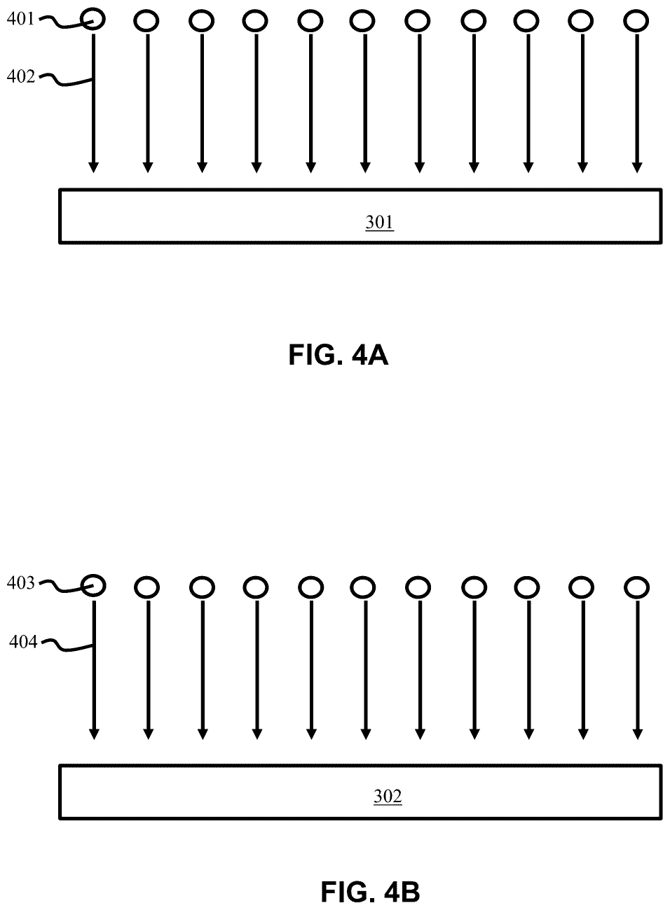

A method for direct diffusion bonding a diamond substrate with a second material substrate according to an aspect of the present disclosure may be understood by referring to flow diagram depicted in FIG. 2 and the diagrams depicted in FIG. 3A through FIG. 8. A diamond wafer may be cut from a boule of grown diamond forming a diamond substrate. Initially the diamond substrate and second material substrate may be planarized and/or polished to create a suitable bonding surface as indicated at 201 in FIG. 2. The surface of the diamond substrate may be polished to an arithmetic average surface roughness (Ra) of less than 200 nanometers and preferably less than 100 nanometers and more preferably 20 to 50 nanometers. Low surface roughness facilitates quantum effects at the bonding surfaces improve adherence thereby aiding bonding of the two substrates.

FIG. 3A graphically depicts an example of polishing of the diamond substrate in the method for direct diffusion bonding with surface treatment. The diamond substrate 301 here may be polished mechanically for example and without limitation, using diamond polishing compound 306 and a rotating polishing pad 303. In some implementations the diamond substrate 301 may be chemically and mechanically polished with a mechanical polishing wheel using heat and chemical oxidant such as for example and without limitation, NaNO3, KNO3, KOH, KC103, K2Cr2O7, H2O2, HClO, HNO3, H2SO4, AgO, Cr2O3, MnO2, BaO2, PdO2, K2FeO4, KmnO4, Na2MoO4, KIO4, (NH4)2S2O8 etc. During polishing the diamond substrate may be heated to a suitable temperature for the activity chemical oxidant. The mechanical polishing wheel may be made from a material chosen to create the lowest surface roughness for the diamond substrate. In some implementations the chemical oxidant may be mixed with polishing compound (e.g., diamond abrasive polishing compound) to further reduce surface roughness. In some implementations rough diamond or other substrates may also be bonded without having to polish them. Instead, the adhesion layer would be polished. For example and without limitation, bonding layers, diffusion barrier, and adhesion layers may be formed on rough diamond. The adhesion layer may be formed to a thickness roughly 3-5 times the surface roughness of the diamond. The adhesion layer, e.g., copper, would then be polished to the desired roughness, e.g., 200 nm or less, 100 nm or less or 20-50 nm. Bonding could then take place with application of pressure and heat.

FIG. 3B graphically depicts the polishing of the second material substrate in the method for direct diffusion bonding with surface treatment. Here, polishing is dependent upon the type of material being polished. Generally polishing of the second material substrate is carried out in a similar manner as the diamond substrate with the second material substrate 302 may be subjected to pressure against a turning polishing wheel 304. A polishing compound suitable for the second material may be applied to the polishing wheel to aid polishing. In some implementations a chemical etchant or oxidant and heat along with mechanical polishing may be used with the second material substrate. The chemical etchant or oxidant may be any suitable etchant or oxidant for the material of the second material substrate.

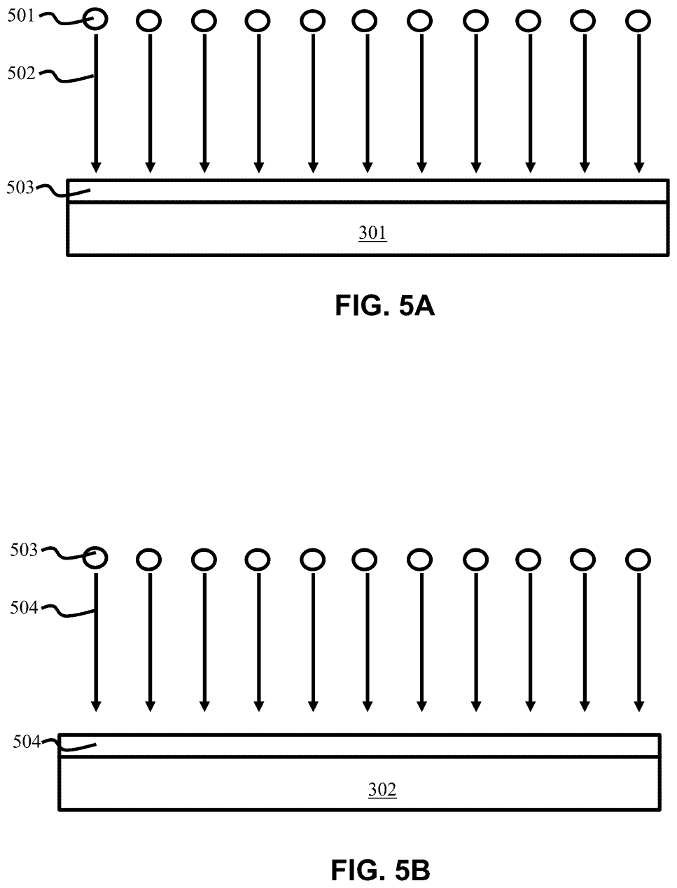

Next the bonding layer may be deposited on the polished surface of the diamond substrate indicated at 202. A bonding layer may optionally be deposited on the polished surface of the second material substrate, as in a similar way. The bonding layer may be any material that allows metals to bond diamond atoms for example and without limitation, titanium. The bonding layer may be deposited to a layer thickness of between 10 nanometers (nm) and 500 nm thick, preferably between 10 nm and 200 nm, more preferably between 10 nm and 100 nm thick. As shown in FIG. 4A atoms of the bonding layer material 401 may be deposited 402 onto the polished surface of the diamond substrate 301 via plasma sputtering under ultrahigh vacuum (UHV) conditions. Any suitable sputtering technique suitable for the chosen bonding layer material may be used to apply a thin film of bonding layer material to the surface of the diamond substrate 301. Similarly, as shown in FIG. 4B atoms of bonding layer material 403 may be deposited 404 onto the polished surface of the second material substrate 302 via plasma sputtering under UHV conditions. Any suitable sputtering method for applying a thin film of the bonding layer material to the second material may be used.

After deposition of the bonding layer(s), a diffusion barrier layer may optionally be deposited on the bonding layer over the polished surface of the diamond substrate, as indicated at 203. A diffusion barrier may optionally be deposited over the polished surface of the second material substrate in a similar manner. The diffusion barrier layer may be made from any suitable material that blocks diffusion of metal atoms into the diamond substrate and/or the second material substrate, for example and without limitation Nickel. The diffusion barrier layer may be deposited to a layer thickness of between 10 nm and 500 nm preferably between 10 nm and 200 nm, more preferably between 10 nm and 100 nm thick. As shown in FIG. 5A atoms of the diffusion barrier layer material 501 may be deposited 502 onto the bonding layer 503 over polished surface of the diamond substrate 301 via plasma sputtering under UHV conditions. Any suitable sputtering method for applying a thin film of the diffusion barrier layer material to the bonding layer over the diamond substrate may be used. Similarly, as shown in FIG. 5B atoms of the diffusion barrier layer material 503 may be deposited 504 onto the bonding layer 503 over the polished surface of the second material substrate 302. Any suitable sputtering method for applying a thin film of bonding layer material to second material may be used.

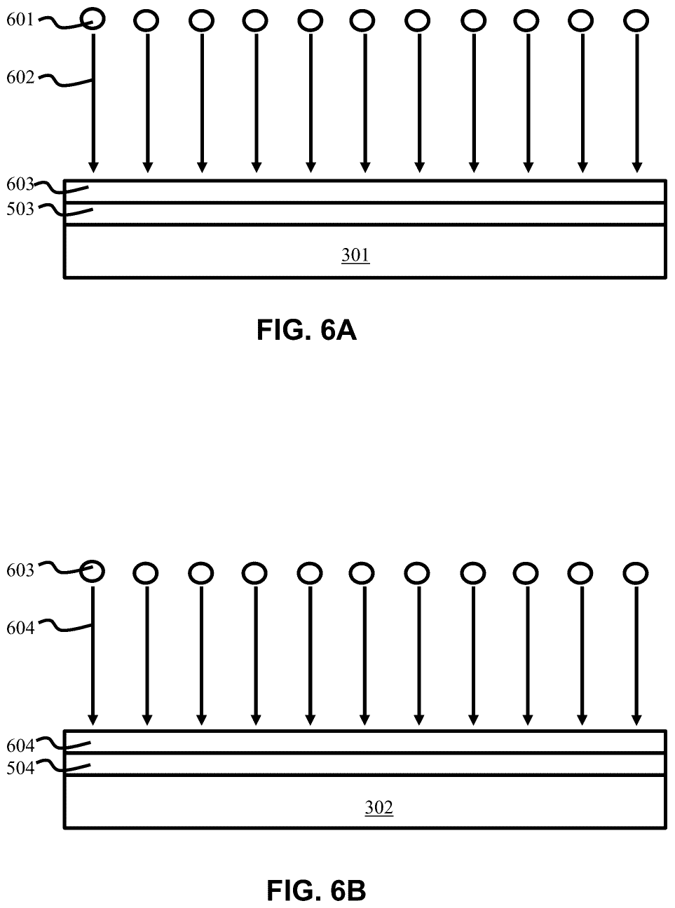

Next an adhesion layer may optionally be deposited on the diffusion barrier layer over the bonding layer and polished surface of the diamond substrate as indicated at 204. A diffusion barrier may also optionally be deposited over the polished surface of the second material substrate in a similar way. The adhesion layer may be any material that aids in the adhesion of the diamond substrate with the second material substrate and may be for example and without limitation periodic table group 11 metals including silver, gold, and copper preferably silver or gold. The adhesion layer additionally absorbs the stress between the diamond substrate and the second material substrate that develops during bonding. The adhesion layer may be formed to a layer thickness between 100 nm and 20 micrometers (μm), preferably 2 μm to 5 μm. As shown in FIG. 6A atoms of the adhesion layer material 601 may be deposited 602 onto the diffusion barrier layer 603 over the bonding layer 503 and the polished surface of the diamond substrate 301 via plasma sputtering under UHV conditions. Any suitable sputtering method for applying a thin film of the diffusion barrier layer material to the bonding layer over the diamond substrate may be used. Similarly, as shown in FIG. 6B atoms of the adhesion layer material 603 may be deposited 404 onto the diffusion barrier layer 603 over the bonding layer 503 and the polished surface of the second material substrate 302. Any suitable sputtering method for applying a thin film of bonding layer material to second material may be used. While the above discussed depositions are described as performed with sputtering under UHV conditions, aspects of the present disclosure are not so limited and the depositions may be performed using any suitable deposition method, for example and without limitation; atomic layer deposition, pulsed layer deposition, MOCVD, MBE, CVD, or electron beam deposition.

In alternative implementations rough diamond or other substrates may be bonded without having to polish them directly. Instead, the adhesion layer would be polished prior to bonding. For example, bonding, diffusion barrier, and adhesion layers may be formed on an unpolished diamond substrate. The adhesion layer may then be formed to a thickness roughly 3-5 times the surface roughness of the diamond. The adhesion layer, e.g., copper, would then be polished to the desired roughness, e.g., 200 nm or less, 100 nm or less or 20-50 nm. The polished surface of the adhesion layer could then be bonded to another suitably polished substrate surface with application of pressure and heat. Such implementations are extremely economically advantageous since it is much less expensive and simpler to polish an adhesion layer, such as copper, silver or gold than to polish diamond.

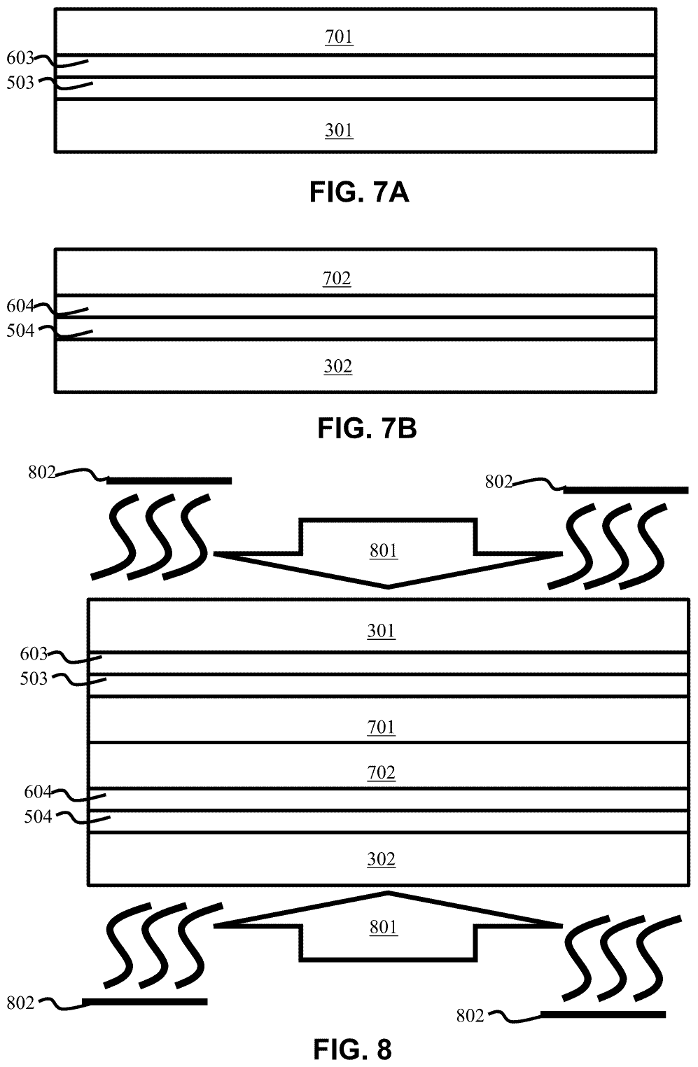

FIG. 7A-7B graphically depict substrate surface treatment stacks prior to a bonding step in the method for direct diffusion bonding with surface treatment of a diamond substrate with a second material substrate according to an aspect of the present disclosure. As shown in FIG. 7A before bonding the diamond substrate 301 may have different material layers stacked onto the polished surface. The layers as shown are the adhesion layer 701, diffusion barrier layer 603, and bonding layer 503. It should be understood that the adhesion layer 701 and diffusion barrier layer 603 may be optional depending on the type of material being bonded to diamond substrate. For example, and without limitation, if the second material substrate is gold, the adhesion layer may be omitted as the gold second material substrate adheres well to the bonding layer, e.g., gold, silver, copper, palladium. Similarly as shown in FIG. 7B before bonding, the second material substrate 302 may have different material layers stacked onto the polished surface. The layers as shown are the adhesion layer 702, diffusion barrier layer 604, and bonding layer 504. Adhesion layer 702 and diffusion barrier layer 602 may be optional depending on the type of material of the second material substrate. In some implementations an adhesion layer including gold may be used to provide a thermally conductive interface with a mirrored surface that is resistant to tarnishing. In other implementations an adhesion layer including silver may be used to provide improved heat conduction over gold, and tarnishing is not a concern. In yet other implementations an adhesion layer including copper may be used where cost is a concern, and the copper is not exposed to oxygen as oxidation changes the properties of the copper.

FIG. 8 graphically depicts a bonding step in the method for direct diffusion bonding with surface treatment of a diamond substrate with a second material substrate according to an aspect of the present disclosure. After formation layers on the polished substrate sufficient force and heat are applied to bond the Diamond Substrate to the second material substrate 205. Here, the diamond substrate 301 with adhesion layer 701, diffusion barrier layer 603, and bonding layer 503 stacked on the polished surface of the substrate is placed in a heating press. The second material substrate 302 is placed in the same heating press with the exposed surface of the adhesion layer 702 on the second material substrate facing the exposed surface of the adhesion layer 701 on diamond substrate such that both are touching. As shown the second material substrate also has a stack of adhesion layer 702, diffusion barrier layer 604, and bonding layer 504 on the polished surface of the second material. It should be noted that the stack of layers on each substrate may differ depending upon implementation and the material of the second material substrate.

Bonding of the diamond substrate to the second material substrate may be accomplished through the application of heat 802 and pressure 801 in compression using the heating press. The heat 802 may be applied simultaneously with compressing pressure 801 to integrate the layer stacks into crystal structure of the diamond substrate and the second material substrate. The heating press may be heated to between 250 degrees Celsius and 270 degrees Celsius during compression and the press may be used to apply between 25 Megapascals to 40 megapascals of pressure to compress the two substrates together prior to heating. In some alternative implementations a press and oven may be used to heat and compress the substrates together instead of a heating press.

Thus, compositions of matter, such those depicted in FIGS. 1A-1E, may be formed. Bonding a diamond substrate to a second material substrate in accordance with the method discussed above may create an interfacial region and strong bond that provides several advantages over prior compositions created by other methods. For example, and without limitation, the described composition may provide a dense substrate composition with no cavities between substrates compared to prior methods of substrate bonding such as sintering which may leave pockets of unbonded sintering material resulting in a density of as low as 98% or soldering which may have voids created during soldering. Additionally compared to sintering and soldering, which create a sintering intermediate layer and soldering intermediate layer respectively, the current composition has no intermediate layer as the layer stack becomes integrated into the crystal structure of the substrates during bonding. As a result, another benefit of the current composition is that it is as stress resilient as the underlying material of the substrate unlike soldering or sintering which include intermediate layers which are points of failure. Finally, the method is simpler and cheaper than sintering because it does not require expensive and complex sintering pastes and provides greater thermal conductivity than soldering as it lacks a low thermal conductivity solder layer.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A.” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A method for fabrication of a diamond substrate bonded to a second material, comprising:
a) polishing a surface of the diamond substrate and a surface of the second material;
b) depositing a transition metal layer on the surface of the diamond;
c) depositing a diffusion barrier metal over the transition metal layer on the diamond substrate;
d) applying sufficient heat and pressure to bond the surface of the diamond substrate to the surface of the second material.

2. The method of claim 1, wherein the transition metal layer includes titanium.

3. The method of claim 1 further comprising depositing a periodic group 11 metal or palladium over the nickel on the diamond substrate.

4. The method of claim 3 wherein the second material includes materials composed of elements other than periodic group 11 elements.

5. The method of claim 3 further comprising depositing the periodic group 11 metal or palladium over a nickel layer on the second material.

6. The method of claim 3 wherein the periodic group 11 metal has a layer thickness of between 100 nanometers and 10 micrometers.

7. The method of claim 3 wherein the periodic group 11 metal is silver.

8. The method of claim 3 wherein the periodic group 11 metal is gold.

9. The method of claim 1 further comprising depositing a second transition metal layer on the surface of the second material.

10. The method of claim 9, wherein the second transition metal layer includes titanium.

11. The method of claim 1 further comprising depositing nickel over the surface of the second material.

12. The method of claim 1 wherein the surface of the diamond substrate is polished to an arithmetic average roughness of less than 200 nanometers.

13. The method of claim 1 wherein the titanium layer is between 10 nanometers and 500 nanometers thick.

14. The method of claim 1 wherein the Nickel has a layer thickness of between 10 nanometers and 500 nanometers.

15. The method of claim 1 wherein applying the sufficient heat and pressure to bond the surface of the diamond substrate to the surface of the second material includes heating the diamond substrate and second substrate material to a temperature between 250° Celsius and 270° Celsius.

16. The method of claim 1 wherein applying the sufficient heat and pressure to bond the surface of the diamond substrate to the surface of the second material includes compressing the diamond substrate and the second substrate material together with 25 Megapascals to 40 Megapascals of pressure.

17. The method of claim 1 wherein applying the sufficient heat and pressure to bond the surface of the diamond substrate to the surface of the second material creates an interfacial bonding region between the diamond substrate and the second substrate wherein the interfacial bonding region includes atoms from the Titanium layer and Nickel incorporated among atoms in the crystal structure of the at least the diamond substrate.

18. A composition of matter, comprising:
a diamond substrate
a second material substrate
an interfacial region in the diamond substrate and the second material substrate wherein the interfacial region integrates transition metal atoms and diffusion barrier metal atoms into at least a crystal structure of the diamond substrate

19. The composition of matter of claim 18 wherein the interfacial region further incorporates atoms from periodic group 11 or palladium into at least the crystal structure of the diamond substrate.

20. The composition of matter of claim 19 wherein the periodic group 11 atoms are gold atoms.

21. The composition of matter of claim 19 wherein the periodic group 11 atoms are silver atoms and the transition metal atoms are titanium atoms.

22. The composition of matter of claim 18 wherein interfacial region further integrates titanium atoms and silver atoms into the crystal structure of the second substrate material.
